(19) United States
(12) Patent Application Publication
(10) Pub. No.: US 2025/0336457 A1
(43) Pub. Date: Oct. 30, 2025

(54) MEMORY DEVICE AND METHOD OF OPERATING THE SAME

(71) Applicant: SK hynix Inc., Icheon-si Gyeonggi-do (KR)

(72) Inventor: Nam Cheol JEON, Icheon-si Gyeonggi-do (KR)

(73) Assignee: SK hynix Inc., Icheon-si Gyeonggi-do (KR)

(21) Appl. No.: 18/904,781

(22) Filed: Oct. 2, 2024

(30) Foreign Application Priority Data
Apr. 30, 2024 (KR) 10-2024-0057695

(51) Int. Cl. G11C 16/34; G11C 16/04; G11C 16/08; G11C 16/14; G11C 16/32; H10B 43/35

(52) U.S. Cl. CPC G11C 16/349; G11C 16/0483; G11C 16/08; G11C 16/14; G11C 16/32; H10B 43/35

(57) ABSTRACT

Provided herein may be a memory device and a method of operating the same. The memory device may include a memory block including first and second select transistors connected between a source line and a bit line, and memory cells connected between the first and second select transistors, a peripheral circuit configured to adjust threshold voltages of the first and second select transistors and the memory cells, and a control circuit configured to, depending on a cycle count of the memory block during an erase operation on the memory block, control the peripheral circuit to adjust a pass voltage that is applied to a first select line connected to a gate of the first select transistor and to a second select line connected to a gate of the second select transistor.

### CROSS-REFERENCE TO RELATED APPLICATION

The present application claims priority under 35 U.S.C. § 119(a) to Korean patent application number 10-2024-0057695 filed on Apr. 30, 2024, in the Korean Intellectual Property Office, the entire contents of which application is incorporated herein by reference.

### BACKGROUND

### 1. Technical Field

Various embodiments of the present disclosure generally relate to a memory device and a method of operating the memory device, and more particularly to a memory device having a three-dimensional (3D) structure and a method of operating the memory device.

### 2. Related Art

A memory device may include a memory cell array in which data is stored and a peripheral circuit that performs a program operation, a read operation, or an erase operation.

The memory cell array may include a plurality of memory blocks, each of which including a plurality of memory cells.

The peripheral circuit may include a control circuit that controls the overall operation of the memory device in response to a command transmitted from an external controller and may include circuits that perform a program operation, an erase operation, or a read operation under the control of the control circuit.

The program operation and the erase operation may be defined as a cycle. For example, when one program operation and one erase operation are performed on a memory block selected from among memory blocks, the number of cycles (i.e., cycle count) of the selected memory block may be one.

Because the memory device may be degraded whenever a program operation, an erase operation, or a read operation is performed, the degree of degradation may be determined based on a cycle count. Therefore, as the cycle count increases, the electrical characteristics of the memory device may be degraded.

### SUMMARY

An embodiment of the present disclosure may provide for a memory device. The memory device may include a memory block including first and second select transistors connected between a source line and a bit line, and memory cells connected between the first and second select transistors, a peripheral circuit configured to adjust threshold voltages of the first and second select transistors and the memory cells, and a control circuit configured to, depending on a cycle count of the memory block during an erase operation on the memory block, control the peripheral circuit to adjust a pass voltage that is applied to a first select line connected to a gate of the first select transistor and to a second select line connected to a gate of the second select transistor.

An embodiment of the present disclosure may provide for a memory device. The memory device may include a memory block including first and second select transistors connected between a source line and a bit line, and memory cells connected between the first and second select transistors, a peripheral circuit configured to adjust threshold voltages of the first and second select transistors and the memory cells, and a control circuit configured to, depending on the cycle count of the memory block during an erase operation on the memory block, control the peripheral circuit to adjust a compensation voltage that is applied to word lines connected to gates of the memory cells.

An embodiment of the present disclosure may provide for a method of operating a memory device. The method may include during an erase operation performed on a memory block including first and second select transistors connected between a source line and a bit line and memory cells connected between the first and second select transistors, comparing a cycle count of the memory block with an initial reference count, based on a result of the comparison between the cycle count and the initial reference count, setting a time at which a pass voltage is applied to a first select line connected to a gate of the first select transistor and a second select line connected to a gate of the second select transistor, applying an erase voltage to at least one of the source line and the bit line, and applying the pass voltage to the first and second select lines at a set time while the erase voltage is increasing up to a target level.

An embodiment of the present disclosure may provide for a method of operating a memory device. The method may include, during an erase operation performed on a memory block including first and second select transistors connected between a source line and a bit line and memory cells connected between the first and second select transistors, comparing a cycle count of the memory block with an initial reference count, based on a result of the comparison between the cycle count and the initial reference count, setting a level of a pass voltage to be applied to a first select line connected to a gate of the first select transistor and a second select line connected to a gate of the second select transistor, applying an erase voltage to at least one of the source line and the bit line, and applying the pass voltage having the set level to the first and second select lines at a set time while the erase voltage is increasing up to a target level.

An embodiment of the present disclosure may provide for a method of operating a memory device. The method may include, during an erase operation performed on a memory block including first and second select transistors connected between a source line and a bit line and memory cells connected between the first and second select transistors, applying an erase voltage to at least one of the source line and the bit line, applying a first compensation voltage to word lines connected to gates of the memory cells while the erase voltage is increasing up to a target level, and applying a second compensation voltage, the second compensation voltage being higher than the first compensation voltage, to the word lines while the erase voltage is maintained at the target level, wherein a time at which the second compensation voltage is applied to the word lines is adjusted depending on a cycle count of the memory block.

### BRIEF DESCRIPTION OF THE DRAWINGS

FIG. 1 is a diagram illustrating a memory device.

FIG. 2 is a diagram illustrating the arrangement of a memory cell array and a peripheral circuit.

FIG. 3 is a circuit diagram illustrating a memory block.

FIG. 4 is a perspective view illustrating a memory block.

FIG. 5 is a diagram illustrating a select transistor.

FIG. 6 is a diagram illustrating changes in the threshold voltages of select transistors.

FIG. 7 is a flowchart illustrating an erase operation according to a first embodiment of the present disclosure.

FIG. 8 is a timing diagram illustrating the erase operation according to the first embodiment of the present disclosure.

FIG. 9 is a diagram illustrating a pass voltage application time depending on a cycle period according to the first embodiment of the present disclosure.

FIG. 10 is a flowchart illustrating an erase operation according to a second embodiment of the present disclosure.

FIG. 11 is a timing diagram illustrating the erase operation according to the second embodiment of the present disclosure.

FIG. 12 is a diagram illustrating a pass voltage depending on a cycle period according to the second embodiment of the present disclosure.

FIG. 13 is a flowchart illustrating an erase operation according to a third embodiment of the present disclosure.

FIG. 14 is a timing diagram illustrating the erase operation according to the third embodiment of the present disclosure.

FIG. 15 is a diagram illustrating a pass voltage application time and a pass voltage depending on a cycle period according to the third embodiment of the present disclosure.

FIG. 16 is a flowchart illustrating an erase operation according to a fourth embodiment of the present disclosure.

FIG. 17 is a timing diagram illustrating the erase operation according to the fourth embodiment of the present disclosure.

FIG. 18 is a diagram illustrating a second compensation voltage application time depending on a cycle period according to the fourth embodiment of the present disclosure.

FIG. 19 is a diagram illustrating a memory card system to which a memory system according to an embodiment of the present disclosure is applied.

FIG. 20 is a diagram illustrating a solid state drive (SSD) system to which a memory device according to an embodiment of the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below and may be modified in various forms and replaced with other equivalent embodiments.

Hereinafter, although the terms “first” and “second” may be used herein to describe various elements, these elements should not be limited by these terms. The terms are used to distinguish one element from other elements.

Various embodiments of the present disclosure are directed to a memory device that can prevent the reliability of the memory device from deteriorating due to the degradation of the memory device.

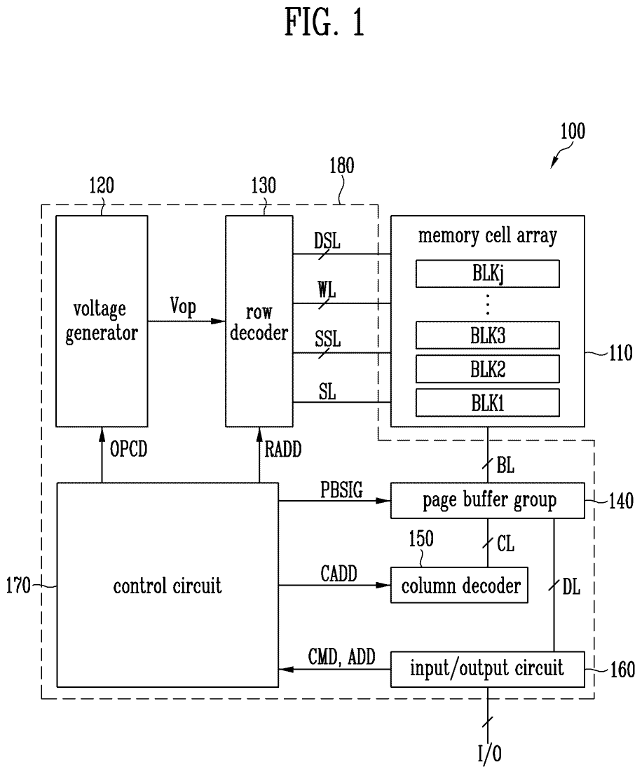

FIG. 1 is a diagram illustrating a memory device.

Referring to FIG. 1, a memory device 100 may include a memory cell array 110 and a peripheral circuit 180.

The memory cell array 110 may include first to j-th memory blocks BLK1 to BLKj. Each of the first to j-th memory blocks BLK1 to BLKj may include memory cells capable of storing data. Drain select lines DSL, word lines WL, source select lines SSL, and a source line SL may be connected to each of the first to j-th memory blocks BLK1 to BLKj, and bit lines BL may be connected in common to the first to j-th memory blocks BLK1 to BLKj.

Each of the first to j-th memory blocks BLK1 to BLKj may be formed in a two-dimensional (2D) structure or a three-dimensional (3D) structure. Each memory block having a 2D structure may include memory cells arranged in parallel on a substrate. Each memory block having a 3D structure may include memory cells stacked on a substrate in a vertical direction. In the present embodiment, memory blocks formed in a 3D structure are disclosed.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 180 may perform a program operation that stores data in the memory cell array 110, a read operation that outputs data stored in the memory cell array 110, and an erase operation that erases data stored in the memory cell array 110. For example, the peripheral circuit 180 may include a voltage generator 120, a row decoder 130, a page buffer group 140, a column decoder 150, an input/output circuit 160, and a control circuit 170.

In response to an operation code OPCD, the voltage generator 120 may generate various operating voltages Vop that are used for a program operation, a read operation, or an erase operation. For example, in response to the operation code OPCD, the voltage generator 120 may generate a program voltage, a turn-on voltage, a turn-off voltage, a verify voltage, a read voltage, a pass voltage, or an erase voltage. Each of the operating voltages Vop generated by the voltage generator 120 may have various levels. The operating voltages Vop may be applied to the drain select lines DSL, the word lines WL, the source select lines SSL, and the source line SL of a memory block selected through the row decoder 130.

The program voltage may be a voltage that is applied to a word line selected from among the word lines WL during a program operation and may be used to increase the threshold voltages of memory cells connected to the selected word line. The turn-on voltage may be applied to the drain select lines DSL or the source select lines SSL and may be used to turn on drain select transistors or source select transistors. The turn-off voltage may be applied to the drain select lines DSL or the source select lines SSL and may be used to turn off the drain select transistors or the source select transistors. The verify voltage may be used in a verify operation that determines whether the threshold voltages of selected memory cells have increased to a target level. The verify voltage may be set to various levels according to the target level and may be applied to the selected word line. The read voltage may be applied to the selected word line during a read operation performed on the selected memory cells. For example, the read voltages may be set to various levels according to the program scheme for the selected memory cells. The pass voltage may be a voltage that is applied to unselected word lines, among the word lines WL, during a program or read operation and may be used to turn on memory cells connected to the unselected word lines. The erase voltages may be used in an erase operation that erases the memory cells included in the selected memory block and may be applied to the word lines WL.

The row decoder 130 may transmit the operating voltages Vop to the drain select lines DSL, the word lines WL, the source select lines SSL, and the source line SL, which are connected to a memory block selected according to a row address RADD. For example, the row decoder 130 may be connected to the voltage generator 120 through global lines GL and may be connected to the first to j-th memory blocks BLK1 to BLKj through the drain select lines DSL, the word lines WL, the source select lines SSL, and the source line SL. In an embodiment, the source line SL may be connected to a separate source line driver (not illustrated) without being connected to the row decoder 130.

The page buffer group 140 may include page buffers (not illustrated) connected to the first to j-th memory blocks BLK1 to BLKj, respectively. The page buffers (not illustrated) may be connected to the first to j-th memory blocks BLK1 to BLKj, respectively, through the bit lines BL. During a read operation, the page buffers (not illustrated) may sense the currents or voltages of the bit lines varying with the threshold voltages of the selected memory cells in response to page buffer control signals PBSIG and may temporarily store the sensed data.

The column decoder 150 may be configured such that data is transferred between the page buffer group 140 and the input/output circuit 160 in response to a column address CADD. For example, the column decoder 150 may be connected to the page buffer group 140 through column lines CL and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 170 and may transmit the data, received from the external controller through the input/output lines I/O, to the page buffer group 140 through the data lines DL. Alternatively, the input/output circuit 160 may output data, received from the page buffer group 140, to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to a program operation, the control circuit 170 may control the devices included in the peripheral circuit 180 so that the program operation is performed on a memory block selected by the address ADD. When the command CMD input to the control circuit 170 is a command corresponding to a read operation, the control circuit 170 may control the devices included in the peripheral circuit 180 so that the read operation is performed on a memory block selected by the address and read data is output. When the command CMD input to the control circuit 170 is a command corresponding to an erase operation, the control circuit 170 may control the devices included in the peripheral circuit 180 so that the erase operation is performed on a selected memory block.

The control circuit 170 may count the number of cycles (i.e., cycle count) of the memory device 100 and may store the count value. For example, the control circuit 170 may count the number of cycles (cycle count) of each of first to j-th memory blocks BLK1 to BLKj and may store respective count values.

The control circuit 170 may change the erase operation depending on the cycle count of the selected memory block during an erase operation on the selected memory block. For example, depending on the cycle count, the control circuit 170 may output the operation code OPCD to adjust a time at which the pass voltage is applied to the select lines of the selected memory block, the level of the pass voltage, or a combination thereof. In response to the operation code OPCD, the voltage generator 120 may adjust and output a timing-adjusted pass voltage, a level-adjusted pass voltage, or a combination thereof.

The control circuit 170 may set the time at which the pass voltage is applied to the select lines to be delayed as the cycle count of the selected memory block increases. The control circuit 170 may set the level of the pass voltage to be higher as the cycle count of the selected memory block increases. The control circuit 170 may set the level of the compensation voltage to be higher as the cycle count of the selected memory block increases.

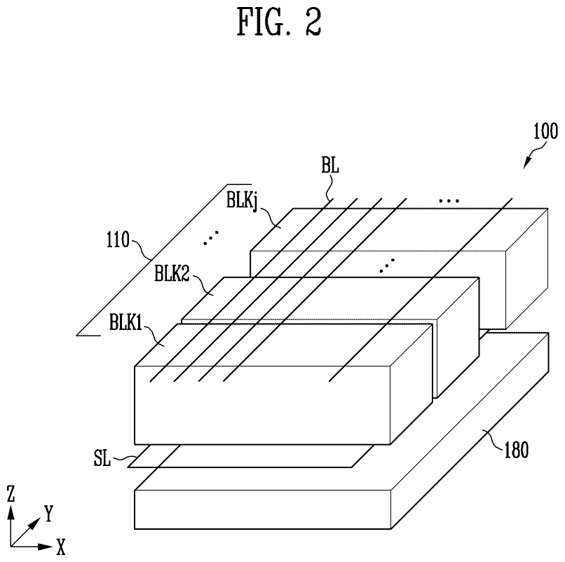

FIG. 2 is a diagram illustrating the arrangement of a memory cell array and a peripheral circuit.

Referring to FIG. 2, the memory device 100 may include a peripheral circuit 180 and a memory cell array 110. The peripheral circuit 180 may be disposed on a substrate (not illustrated), and the memory cell array 110 may be disposed over the peripheral circuit 180. The memory cell array 110 may include first to j-th memory blocks BLK1 to BLKj. Bit lines BL may be disposed on the first to j-th memory blocks BLK1 to BLKj, and a source line SL may be disposed under the first to j-th memory blocks BLK1 to BLKj. Unlike the structure illustrated in FIG. 2, the bit lines BL may be disposed under the first to j-th memory blocks BLK1 to BLKj, and the source line SL may be disposed on the first to j-th memory blocks BLK1 to BLKj.

The plurality of bit lines BL may be arranged to be spaced apart from each other along an X direction and may extend along a Y direction. The first to j-th memory blocks BLK1 to BLKj may be arranged to be spaced apart from each other along a Y direction. The source line SL may be connected in common to the first to j-th memory blocks BLK1 to BLKj.

The first to j-th memory blocks BLK1 to BLKj may be configured in the same manner. Of the memory blocks, the first memory block BLK1 will be described in detail by way of example.

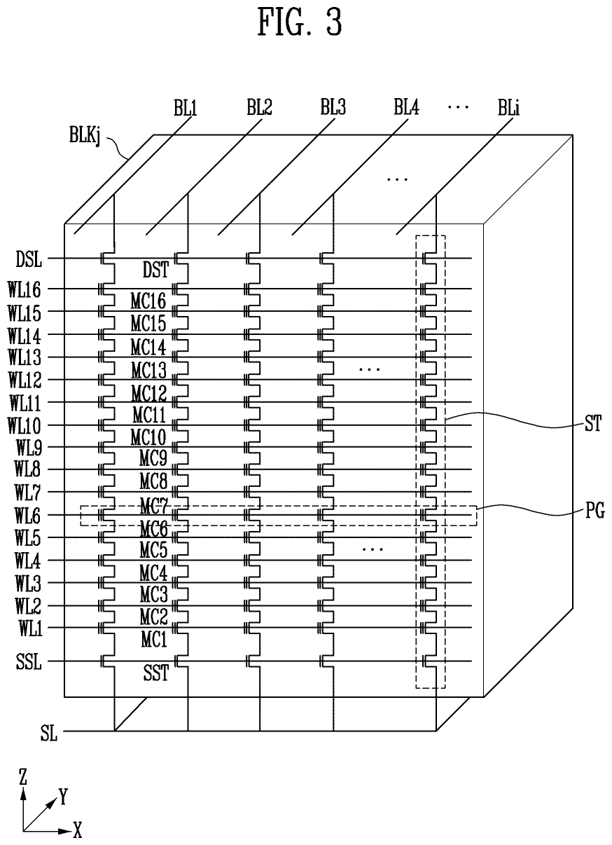

FIG. 3 is a circuit diagram illustrating a memory block.

Referring to FIG. 3, the j-th memory block BLKj, which is any one of the first to j-th memory blocks BLK1 to BLKj, shown in FIG. 2, is illustrated by way of example.

The j-th memory block BLKj may include cell strings ST disposed between the source line SL and first to i-th bit lines BL1 to BLi. The cell strings ST may be arranged to be spaced apart from each other along X and Y directions, and each of the cell strings ST may extend in a Z direction. The first to i-th bit lines BL1 to BLi may be arranged to be spaced apart from each other along the X direction, and each of the first to i-th bit lines BL1 to BLi may extend along the Y direction. FIG. 3 is a diagram illustrating an embodiment of the j-th memory block BLKj, and thus, the numbers of source select transistors SST, first to sixteenth memory cells MC1 to MC16, and drain select transistors DST, which are included in each of the cell strings ST, may vary depending on the memory device.

Gates of source select transistors SST included in different cell strings ST may be connected to a source select line SSL, gates of the first to sixteenth memory cells MC1 to MC16 may be connected to first to sixteenth word lines WL1 to WL16, and gates of drain select transistors DST may be connected to a drain select line DSL. The source select line SSL may be connected in common to the source select transistors SST arranged along the X and Y directions. Alternatively, a source select line SSL connected in common to the source select transistors SST arranged in the X direction and a source select line SSL connected in common to the source select transistors SST arranged in the Y direction may be separated from each other. The first to sixteenth word lines WL1 to WL16 may be connected in common to the memory cells arranged along the X and Y directions. For example, the first memory cells MC1 arranged along the X and Y directions may be connected in common to the first word line WL1, and the second memory cells MC2 arranged along the X and Y directions may be connected in common to the second word line WL2. The drain select line DSL may be connected in common to the drain select transistors DST arranged in the X direction. Different drain select lines DSL may be connected to the drain select transistors DST arranged in the Y direction.

A group of memory cells connected to the same word line may be a page (PG). A program or read operation may be performed on a page (PG) basis. For example, a group of memory cells connected to a selected word line, among memory cells of the cell strings ST connected to a drain select line DSL, selected from among the drain select lines DSL, may be a selected page. The selected page may be a page composed of program target memory cells during a program operation. That is, the selected page may be determined by the drain select lines DSL and the corresponding word line.

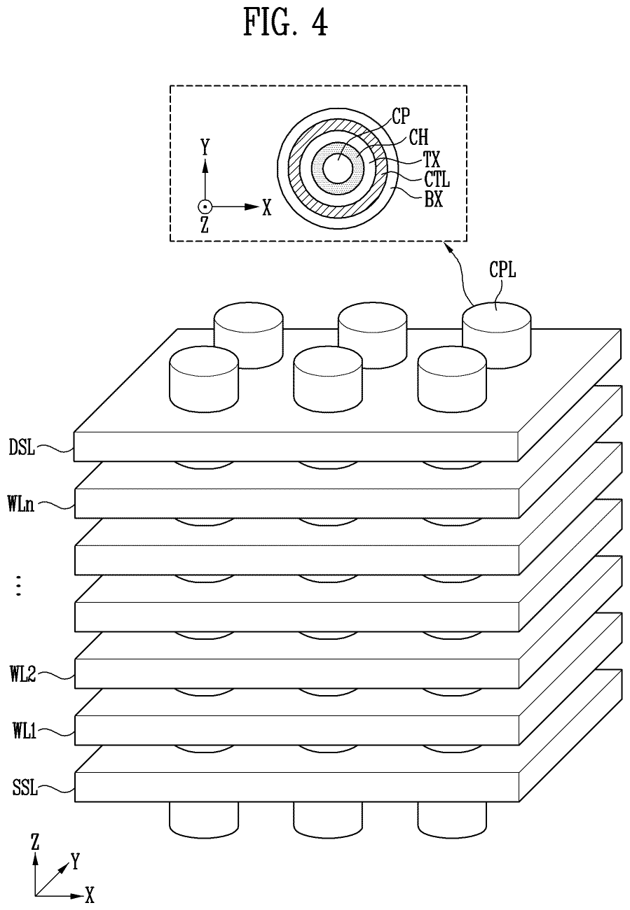

FIG. 4 is a perspective view illustrating a memory block.

Referring to FIG. 4, a portion of the memory block is illustrated. A source select line SSL, first to n-th word lines WL1 to WLn, and a drain select line DSL, which are connected to the memory block, may be stacked to be spaced apart from each other along a Z direction. The source select line SSL, the first to n-th word lines WL1 to WLn, and the drain select line DSL may be formed of the same conductive material. For example, each of the source select line SSL, the first to n-th word lines WL1 to WLn, and the drain select line DSL may be formed of a metal material, such as tungsten (W), molybdenum (Mo), cobalt (Co), or nickel (Ni), or a semiconductor material, such as silicon (Si) or polysilicon (Poly-Si). However, the material is not limited thereto.

Cell plugs CPL may include the cell strings ST, respectively, illustrated in FIG. 3. The cell plugs CPL may penetrate the source select line SSL, the first to n-th word lines WL1 to WLn, and the drain select line DSL. For example, the cell plugs CPL may penetrate the source select line SSL, the first to n-th word lines WL1 to WLn, and the drain select line DSL along the Z direction. Each of the cell plugs CPL may include a core pillar CP, a channel layer CH, a tunnel isolation layer TX, a charge trap layer CTL, and a blocking layer BX. The core pillar CP may have the shape of a cylinder, a rectangular pillar, or a polygonal pillar and may be formed of an insulating material or a conductive material. The channel layer CH may enclose the surface of the core pillar CP and may be formed of polysilicon. The tunnel isolation layer TX may enclose the surface of the channel layer CH and may be formed of an oxide layer. The charge trap layer CTL may enclose the surface of the tunnel isolation layer TX and may be formed of a nitride layer. The blocking layer BX may enclose the surface of the charge trap layer CTL and may be formed of an oxide layer.

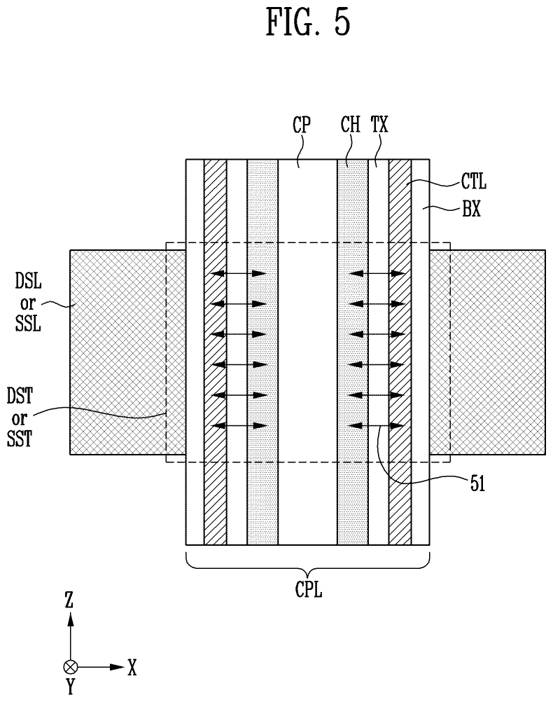

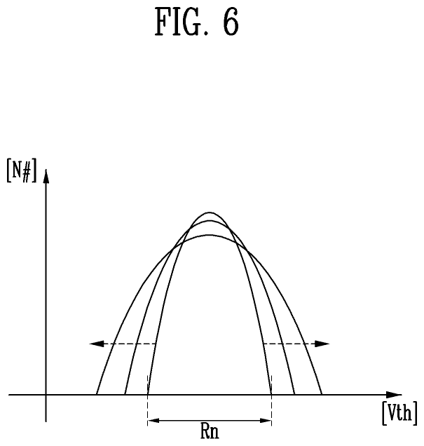

FIG. 5 is a diagram illustrating a select transistor, and FIG. 6 is a diagram illustrating changes in the threshold voltages of select transistors.

Referring to FIGS. 5 and 6, a drain select transistor DST and a source select transistor SST may have different sizes, but the cross-sections of the drain select transistor DST and the source select transistor SST may be identical to each other. FIG. 5 illustrates the cross-section of the drain select transistor DST or the source select transistor SST. The drain select transistor DST may contact a drain select line DSL, and the source select transistor SST may contact a source select line SSL. The cell plug CPL may penetrate the drain select line DSL and the source select line SSL. The cell plug CPL may include a core pillar CP, a channel layer CH enclosing the core pillar CP, a tunnel isolation layer TX enclosing the channel layer CH, a charge trap layer CTL enclosing the tunnel isolation layer TX, and a blocking layer BX enclosing the charge trap layer CTL.

The threshold voltage of the select transistor DST or SST may be changed by electrons trapped in the charge trap layer CTL. The select transistor DST or SST may be programmed before a program operation on a selected memory block is performed, whereby the threshold voltage of the select transistor DST or SST may be increased. The electrons trapped in the select transistor DST or SST may tunnel from the channel layer CH and may then be trapped. The threshold voltage of the select transistor DST or SST may be influenced by various voltages applied to the selected memory block during a program operation or an erase operation performed on the selected memory block. For example, electrons may tunnel (51) between the charge trap layer CTL and the channel layer CH of the select transistor DST or SST. However, as tunneling (51) is repeated, the physical characteristics of the select transistor DST or SST are degraded and then some electrons may be trapped in the charge trap layer CTL or the tunnel isolation layer TX. At this time, a defect in which the trapped electrons cannot escape to other layers may occur.

When the defect occurs in the select transistor DST or SST, the threshold voltage of the select transistor DST or SST may be changed.

The graph illustrated in FIG. 6 indicates threshold voltages Vth and the number of select transistors N #. When the threshold voltage Vth of the select transistor DST or SST falls out of a normal range Rn, the distribution width of the threshold voltage Vth may be widened, resulting in a turn-on level of the select transistor DST or SST being changed. In this case, the potential of the channel layer CH may be changed during the program operation or read operation, which may also affect a sensing operation. That is, when the threshold voltage of the select transistor DST or SST falls out of the normal range Rn, the reliability of the memory device may be deteriorated.

In the present embodiment, even if the cycle count of the memory device increases, an erase operation capable of suppressing the degradation of the select transistor DST or SST is illustrated as an embodiment. The erase operation according to an embodiment of the present disclosure will be described in detail below.

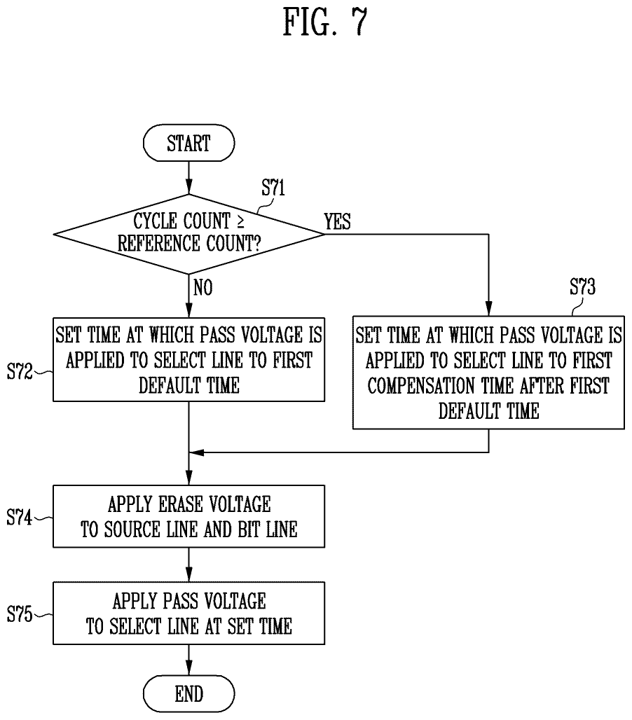

FIG. 7 is a flowchart illustrating an erase operation according to a first embodiment of the present disclosure.

Referring to FIG. 7, when an erase command and an address are input to the memory device, the memory device may compare the number of cycles (cycle count) Nc of a selected memory block with an initial reference count Nrs at step S71. The initial reference count Nrs may be set to the number of times corresponding to an early cycle period of the entire life cycle during which the memory device can be operated. The early cycle period may refer to a period during which the degree of degradation of the memory device is low and within a normal range even if the cycle count Nc increases. That is, a period during which, even when the program and erase operations are performed, the reliability of the memory device does not deteriorate or deteriorates only slightly may be defined as the early cycle period. The initial reference count Nrs may be stored in the control circuit (e.g., 170 of FIG. 1) of the memory device.

The control circuit (e.g., 170 of FIG. 1) of the memory device may determine whether the cycle count Nc of the selected memory block is equal to or greater than the initial reference count Nrs. When the cycle count Nc is less than the initial reference count Nrs (in the case of “No”), the control circuit (e.g., 170 of FIG. 1) may set a time at which a pass voltage is applied to a select line to be a first default time at step S72. Here, the first default time refers to a time basically set in the memory device.

When the cycle count Nc is equal to or greater than the initial reference count Nrs (in the case of “Yes”) at step S71, the control circuit (e.g., 170 of FIG. 1) may set the time at which the pass voltage is applied to the select line to be a first compensation time that is after the first default time at step S73. For example, the first compensation time may be a time that is later than the first default time.

When the time at which the pass voltage is applied is set at step S72 or S73, an erase voltage may be applied to a source line and a bit line connected to the selected memory block at step S74. The erase voltage may be a voltage for erasing the memory cells included in the selected memory block and may be set to a positive voltage higher than 0 V. The erase voltage may be applied only to the source line or to the bit line, but, in the present embodiment, the case in which the erase voltage is applied to the source line and the bit line is described by way of example. Even if the erase voltage is applied to the source line and the bit line, it may take a certain time for the potentials of the source line and the bit line to reach the target level of the erase voltage.

During a period in which the erase voltage is applied to the source line and the bit line and the erase voltage is increasing to the target level, the pass voltage may be applied to the select line at the set time at step S75. At step S75, the select line may include a drain select line and a source line, and the pass voltage may refer to a voltage at which a drain select transistor and a source select transistor can be turned on. The set time used at step S75 may indicate the time set at step S72 or S73. Therefore, when the time at which the pass voltage is applied is set at step S72, the pass voltage may be applied to the select line at the first default time at step S75. When the time at which the pass voltage is applied is set at step S73, the pass voltage may be applied to the select line at the first compensation time at step S75.

That is, when the cycle count of the selected memory block is less than the initial reference count, the pass voltage may be applied to the select line at the first default time during the erase operation, whereas when the cycle count of the selected memory block is equal to or greater than the initial reference count, the pass voltage may be applied to the select line at the first compensation time that is later than the first default time during the erase operation.

During the erase operation according to the first embodiment, a method of applying voltages to lines connected to the selected memory block will be described in detail below.

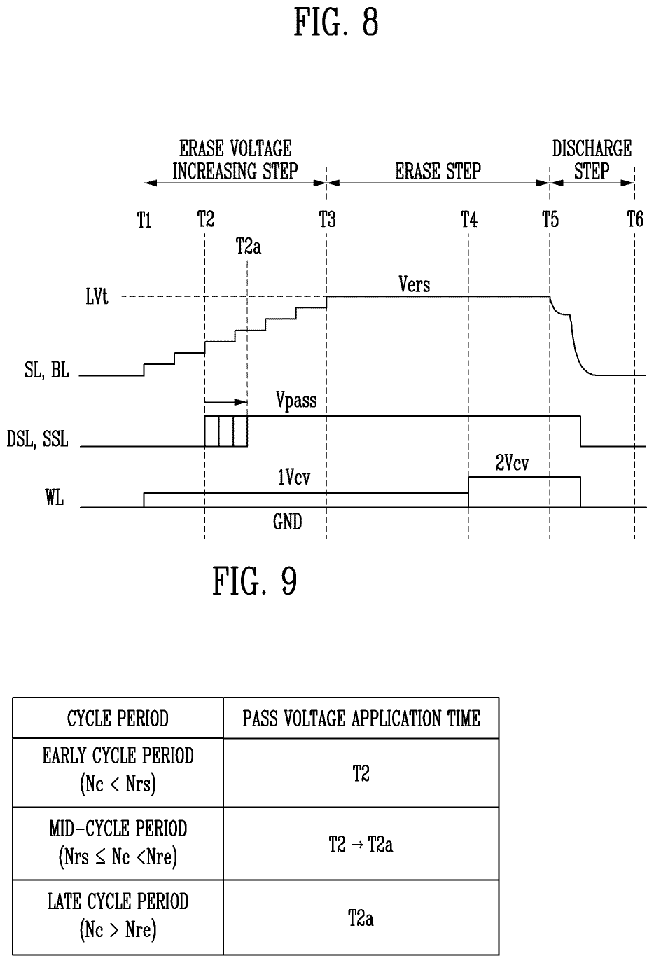

FIG. 8 is a timing diagram illustrating the erase operation according to the first embodiment of the present disclosure.

Referring to FIG. 8, the erase operation may include an erase voltage increasing step, an erase step, and a discharge step and may be performed during a period from time T1 to time T6. The erase voltage increasing step may be performed during a period from time T1 to time T3, the erase step may be performed during a period from time T3 to time T5, and the discharge step may be performed during a period from time T5 to time T6.

At time T1 at which the erase voltage increasing step starts, an erase voltage Vers may be applied to the source line SL and the bit lines BL, and a ground voltage GND and a first compensation voltage 1Vcv that is higher than the ground voltage GND may be applied to word lines WL. The erase voltage Vers may be set to a positive voltage that is higher than the ground voltage GND and may increase in a stepwise or continuous manner to a target level LVt. The first compensation voltage 1Vcv may be set to a positive voltage that is higher than the ground voltage GND and lower than the target level LVt of the erase voltage Vers. The first compensation voltage 1Vcv may be applied to the word lines WL to stably perform the erase operation at the erase step. Although, in the drawing, the first compensation voltage 1Vcv is illustrated as being applied to the word lines WL at time T1, it may be applied to the word lines WL within a period from time T1 to time T2.

During a period from T1 to time T3 in which the erase voltage increasing step is performed, the pass voltage Vpass may be applied to the drain select line DSL and the source select line SSL. The pass voltage Vpass may be used to generate gate induced drain leakage (GIDL) during the erase operation and may be used to prevent the threshold voltages of the drain select transistor and the source select transistor from decreasing at the erase step. Therefore, the pass voltage Vpass may be set to a positive voltage that is higher than the ground voltage GND. For example, the pass voltage Vpass may be set to a voltage that is higher than the first compensation voltage 1Vcv or lower than the target level LVt of the erase voltage Vers.

Time T2 at which the pass voltage Vpass is applied to the drain select line DSL and the source select line SSL may be a first default time stored in advance in the memory device. When the cycle count of the memory block is less than the initial reference count, the time at which the pass voltage Vpass is applied may be set to time T2, which is the first default time. When the cycle count of the memory block is equal to or greater than the initial reference count, the time at which the pass voltage Vpass is applied may be set to a time that is after time T2. When the cycle count of the memory block is equal to or greater than the initial reference count, the time at which the pass voltage Vpass is applied may be delayed incrementally more as the cycle count increases. For example, as the cycle count increases, the time at which the pass voltage Vpass is applied may be delayed incrementally more from time T2 to time T2a. Time T2a may be a first compensation time that is set between time T2 and time T3. That is, even if the cycle count of the memory block is equal to or greater than the initial reference count, the time at which the pass voltage Vpass is applied may be set to not be later than time T3 at which the erase step starts to stably generate GIDL at the erase step.

When time T3 at which the erase voltage Vers applied to the source line SL and the bit line BL reaches the target level LVt is reached, GIDL may be generated on the channel layer, and then the erase operation may be performed.

The erase step may be performed during a period from time T3 to time T5. While the erase step is being performed, a second compensation voltage 2Vcv may be applied to the word lines WL. For example, from time T1 to time T4, the ground voltage GND or the first compensation voltage 1Vcv may be applied to the word lines WL, and from time T4, the second compensation voltage 2Vcv, which is greater than the first compensation voltage 1Vcv, may be applied to the word lines WL. The second compensation voltage 2Vcv may be used to prevent the potential of the channel layer from excessively decreasing at the discharge step. Therefore, the second compensation voltage 2Vcv may be set to be a voltage that is higher than the first compensation voltage 1Vcv or lower than the target level LVt of the erase voltage Vers.

During a period from time T5 to time T6, the source line SL and the bit line BL may be discharged stepwise, and the drain select line DSL, the source select line SSL, and the word lines WL may be simultaneously discharged.

FIG. 9 is a diagram illustrating a pass voltage application time depending on the cycle period according to the first embodiment of the present disclosure.

Referring to FIGS. 8 and 9, the time at which the pass voltage Vpass is applied to the drain select line DSL and the source select line SSL may be changed during an erase operation depending on the cycle period of a memory block. The cycle period may be divided according to the cycle count Nc of the memory block. For example, a period in which the cycle count Nc is less than the initial reference count Nrs may be set as an early cycle period, a period in which the cycle count Nc is equal to or greater than the initial reference count Nrs and less than an end reference count Nre may be set as a mid-cycle period, and a period in which the cycle count Nc is greater than the end reference count Nre may be set as a late cycle period.

The early cycle period may be the period in which the cycle count Nc of the memory block is low, and in which degradation of the memory block does not occur even if the cycle count Nc increases. Therefore, during the early cycle period, the pass voltage may be applied to the drain select line DSL and the source select line SSL at the second time T2, which is the first default time, regardless of the cycle count Nc.

The mid-cycle period may be a period in which the electrical characteristics of the memory block can be degraded as the cycle count Nc of the memory block increases. Therefore, during the mid-cycle period, the time at which the pass voltage is applied may be changed incrementally from time T2 to time T2a depending on the cycle count Nc.

The late cycle period may be a period in which the cycle count Nc of the memory block is high and may be a period in which significant degradation of the memory block occurs. During the late cycle period, it is difficult to greatly improve electrical characteristics even if the pass voltage application time is adjusted. The pass voltage may be applied to the drain select line DSL and the source select line SSL at time T2a, regardless of the cycle count Nc.

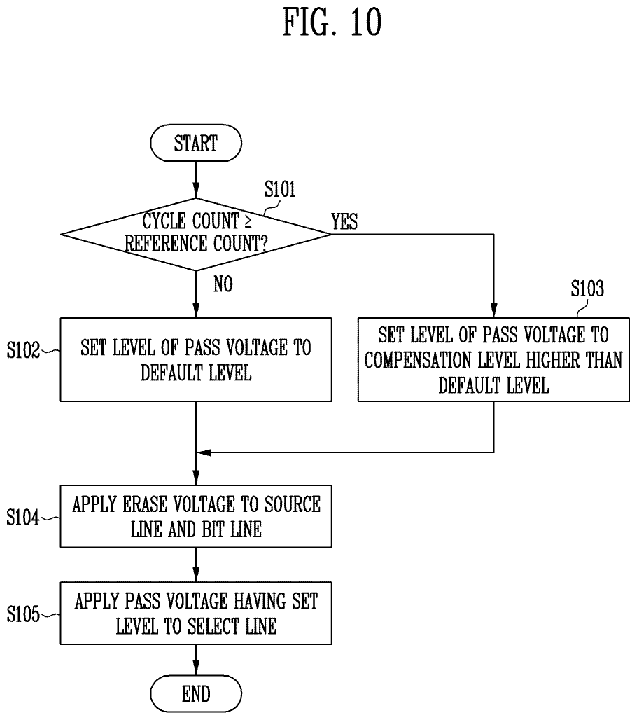

FIG. 10 is a flowchart illustrating an erase operation according to a second embodiment of the present disclosure.

Referring to FIG. 10, when an erase command and an address are input to the memory device, the memory device may compare the number of cycles (cycle count) Nc of a selected memory block with an initial reference count Nrs at step S101. The initial reference count Nrs may be set to the number of times corresponding to an early cycle period of the entire life cycle during which the memory device can be operated. The early cycle period may refer to a period during which the degree of degradation of the memory device is low and within a normal range even if the cycle count Nc increases. That is, a period during which, even when the program and erase operations are performed, the reliability of the memory device does not deteriorate or deteriorates only slightly may be defined as the early cycle period. The initial reference count Nrs may be stored in the control circuit (e.g., 170 of FIG. 1) of the memory device.

The control circuit (e.g., 170 of FIG. 1) of the memory device may determine whether the cycle count Nc of the selected memory block is equal to or greater than the initial reference count Nrs. When the cycle count Nc is less than the initial reference count Nrs (in the case of “No”), the control circuit (e.g., 170 of FIG. 1) may set the level of a pass voltage to be applied to a select line to be a default level at step S102. Here, the default level may refer to a level basically set in the memory device.

When the cycle count Nc is equal to or greater than the initial reference count Nrs (in the case of “Yes”), the control circuit (e.g., 170 of FIG. 1) may set the level of the pass voltage to be applied to the select line to be a compensation level that is higher than the default level at step S103.

When the level of the pass voltage is set at step S102 or S103, an erase voltage may be applied to a source line and a bit line connected to the selected memory block at step S104. The erase voltage may be a voltage for erasing the memory cells included in the selected memory block and may be set to a positive voltage higher than 0 V. The erase voltage may be applied only to the source line or to the bit line, but, in the present embodiment, the case in which the erase voltage is applied to the source line and the bit line is described by way of example. Even if the erase voltage is applied to the source line and the bit line, it may take a certain time for the potentials of the source line and the bit line to reach the target level of the erase voltage.

During a period in which the erase voltage is applied to the source line and the bit line and the erase voltage is increasing up to the target level, the pass voltage having the set level may be applied to the select line at step S105. At step S105, the select line may include a drain select line and a source line, and the pass voltage may refer to a voltage at which a drain select transistor and a source select transistor can be turned on. The level of the pass voltage used at step S105 may be the level set at step S102 or S103. Therefore, when the level of the pass voltage is set at step S102, the pass voltage having the default level may be applied to the select line at step S105. When the level of the pass voltage is set at step S103, the pass voltage having the compensation level may be applied to the select line at step S105.

That is, when the cycle count of the selected memory block is less than the initial reference count, the pass voltage may have the default level during the erase operation, whereas when the cycle count of the selected memory block is equal to or greater than the initial reference count, the pass voltage may have the compensation level that is higher than the default level during the erase operation.

During the erase operation according to the second embodiment, a method of applying voltages to lines connected to the selected memory block will be described in detail below.

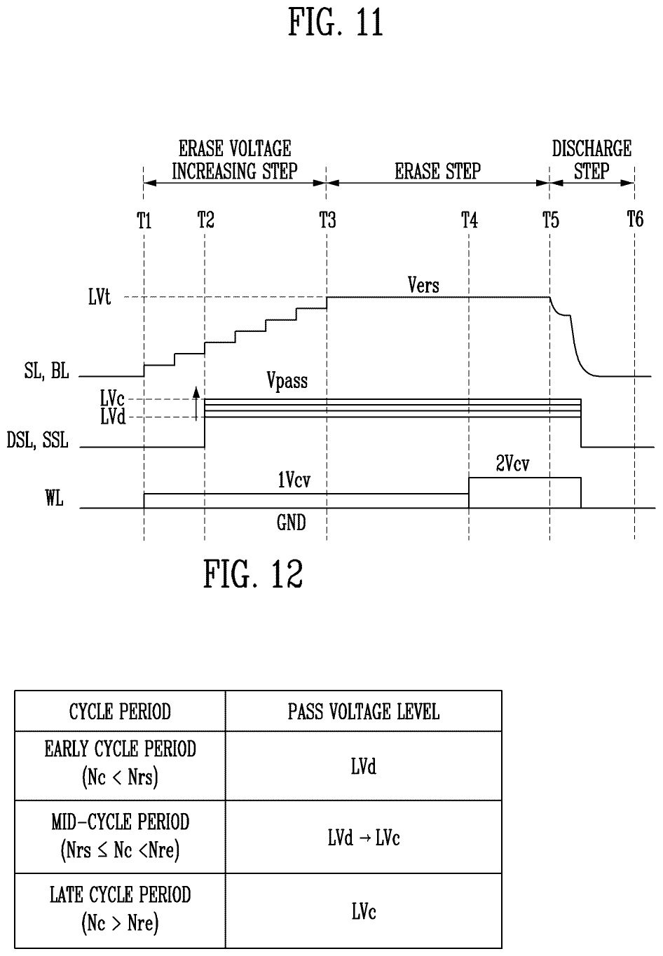

FIG. 11 is a timing diagram illustrating the erase operation according to the second embodiment of the present disclosure.

Referring to FIG. 11, at time T1 at which the erase voltage increasing step starts, an erase voltage Vers may be applied to the source line SL and the bit lines BL, and a ground voltage GND and a first compensation voltage 1Vcv that is higher than the ground voltage GND may be applied to word lines WL. The erase voltage Vers may be set to a positive voltage that is higher than the ground voltage GND and may increase in a stepwise or continuous manner to a target level LVt. The first compensation voltage 1Vcv may be set to a positive voltage that is higher than the ground voltage GND and lower than the target level LVt of the erase voltage Vers. The first compensation voltage 1Vcv may be applied to the word lines WL to stably perform the erase operation at the erase step. Although, in the drawing, the first compensation voltage 1Vcv is illustrated as being applied to the word lines WL at time T1, it may be applied to the word lines WL within a period from time T1 to time T2.

During a period from time T1 to time T3 in which the erase voltage increasing step is performed, the pass voltage Vpass may be applied to the drain select line DSL and the source select line SSL. The pass voltage Vpass may be applied to the drain select line DSL and the source select line SSL at the second time T2 between the first and third times T1-T3. The pass voltage Vpass may be used to generate gate induced drain leakage (GIDL) during the erase operation and may be used to prevent the threshold voltages of the drain select transistor and the source select transistor from decreasing at the erase step. Therefore, the pass voltage Vpass may be set to a positive voltage that is higher than the ground voltage GND. For example, the pass voltage Vpass may have a default level LVd that is higher than the first compensation voltage 1Vcv and lower than the target level LVt of the erase voltage Vers.

When the cycle count of the memory block is less than the initial reference count, the pass voltage Vpass may have the initially set default level LVd. When the cycle count of the memory block is equal to or greater than the initial reference count, the pass voltage Vpass may be set to a level that is higher than the default level LVd. When the cycle count of the memory block is equal to or greater than the initial reference count, the level of the pass voltage Vpass may be set to incrementally increase as the cycle count increases. For example, as the cycle count increases, the level of the pass voltage Vpass may be incrementally increased from the default level LVd to a compensation level LVc. The compensation level LVc may be set between the default level LVd and a level twice the default level LVd.

When time T3 at which the erase voltage Vers applied to the source line SL and the bit line BL reaches the target level LVt is reached, GIDL may be generated on the channel layer, and then the erase operation may be performed.

The erase step may be performed during a period from time T3 to time T5. While the erase step is being performed, a second compensation voltage 2Vcv may be applied to the word lines WL. For example, during a period from time T1 to time T4, the ground voltage GND or the first compensation voltage 1Vcv may be applied to the word lines WL, and from time T4, the second compensation voltage 2Vcv, which is greater than the first compensation voltage 1Vcv, may be applied to the word lines WL. The second compensation voltage 2Vcv may be used to prevent the potential of the channel layer from excessively decreasing at the discharge step. Therefore, the second compensation voltage 2Vcv may be set to be a voltage that is higher than the first compensation voltage 1Vcv or lower than the target level LVt of the erase voltage Vers.

During a period from time T5 to time T6, the source line SL and the bit line BL may be discharged stepwise, and the drain select line DSL, the source select line SSL, and the word lines WL may be simultaneously discharged.

FIG. 12 is a diagram illustrating a pass voltage depending on a cycle period according to the second embodiment of the present disclosure.

Referring to FIGS. 11 and 12, the level of the pass voltage Vpass that is applied to the drain select line DSL and the source select line SSL may be changed during an erase operation depending on the cycle period of a memory block. The cycle period may be divided according to the cycle count Nc of the memory block. For example, a period in which the cycle count Nc is less than the initial reference count Nrs may be set as an early cycle period, a period in which the cycle count Nc is equal to or greater than the initial reference count Nrs and less than an end reference count Nre may be set as a mid-cycle period, and a period in which the cycle count Nc is greater than the end reference count Nre may be set as a late cycle period.

The early cycle period may be the period in which the cycle count Nc of the memory block is low, and in which degradation of the memory block does not occur even if the cycle count Nc increases. Therefore, during the early cycle period, the pass voltage may be set to a default level LVd regardless of the cycle count Nc.

The mid-cycle period may be a period in which the electrical characteristics of the memory block can be degraded as the cycle count Nc of the memory block increases. Therefore, during the mid-cycle period, the pass voltage may be set to incrementally increase between the default level LVd and the compensation level LVc.

The late cycle period may be a period in which the cycle count Nc of the memory block is high and may be a period in which significant degradation of the memory block occurs. During the late cycle period, it is difficult to greatly improve electrical characteristics even if the level of the pass voltage is adjusted. The pass voltage may be set to the compensation level LVc regardless of the cycle count Nc.

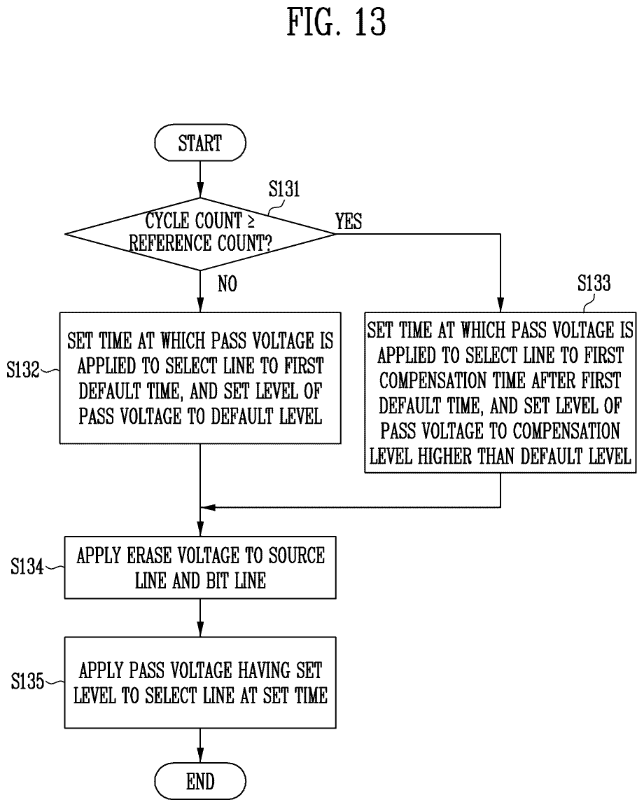

FIG. 13 is a flowchart illustrating an erase operation according to a third embodiment of the present disclosure.

Referring to FIG. 13, when an erase command and an address are input to the memory device, the memory device may compare the number of cycles (cycle count) Nc of a selected memory block with an initial reference count Nrs at step S131. The initial reference count Nrs may be set to the number of times corresponding to an early cycle period of the entire life cycle during which the memory device can be operated. The early cycle period may refer to a period during which the degree of degradation of the memory device is low and within a normal range even if the cycle count Nc increases. That is, a period during which, even when the program and erase operations are performed, the reliability of the memory device does not deteriorate or deteriorates only slightly may be defined as the early cycle period. The initial reference count Nrs may be stored in the control circuit (e.g., 170 of FIG. 1) of the memory device.

The control circuit (e.g., 170 of FIG. 1) of the memory device may determine whether the cycle count Nc of the selected memory block is equal to or greater than the initial reference count Nrs. When the cycle count Nc is less than the initial reference count Nrs (in the case of “No”), the control circuit (e.g., 170 of FIG. 1) may set a time at which a pass voltage is applied to a select line to a first default time, and the level of the pass voltage may be set to a default level at step S132. Here, the first default time may refer to a time basically set in the memory device, and the default level may refer to a level basically set in the memory device.

When the cycle count Nc is equal to or greater than the initial reference count Nrs (in the case of “Yes”) at step S131, the control circuit (e.g., 170 of FIG. 1) may set the time at which the pass voltage is applied to the select line to be a first compensation time that is after the first default time and may set the level of the pass voltage to be a compensation level that is higher than the default level at step S133.

When the pass voltage application time and the level of the pass voltage are set at step S132 or S133, an erase voltage may be applied to a source line and a bit line connected to the selected memory block at step S134. The erase voltage may be a voltage that erases the memory cells included in the selected memory block and may be set to a positive voltage that is higher than 0 V. The erase voltage may be applied only to the source line or to the bit line, but, in the present embodiment, the case in which the erase voltage is applied to the source line and the bit line is described by way of example. Even if the erase voltage is applied to the source line and the bit line, it may take a certain time for the potentials of the source line and the bit line to reach the target level of the erase voltage.

During a period in which the erase voltage is applied to the source line and the bit line and the erase voltage is increasing up to the target level, the pass voltage having the set level may be applied to the select line at the set time at step S135. The select line may include a drain select line and a source line. The pass voltage may refer to a voltage at which a drain select transistor and a source select transistor can be turned on. The set time and the set level used at step S135 may be the time and level that are set at step S132 or S133. Therefore, when the level of the pass voltage and the pass voltage application time are set at step S132, the pass voltage having the default level may be applied to the select line at the first default time at step S135. When the level of the pass voltage and the pass voltage application time are set at step S133, the pass voltage having the compensation level may be applied to the select line at the first compensation time at step S135.

That is, when the cycle count of the selected memory block is less than the initial reference count, the pass voltage having the default level may be applied to the select line at the first default time during the erase operation. That is, when the cycle count of the selected memory block is equal to or greater than the initial reference count, the pass voltage having the compensation level may be applied to the select line at the first compensation time that is later than the first default time during the erase operation.

During the erase operation according to the third embodiment, a method of applying voltages to lines connected to the selected memory block will be described in detail below.

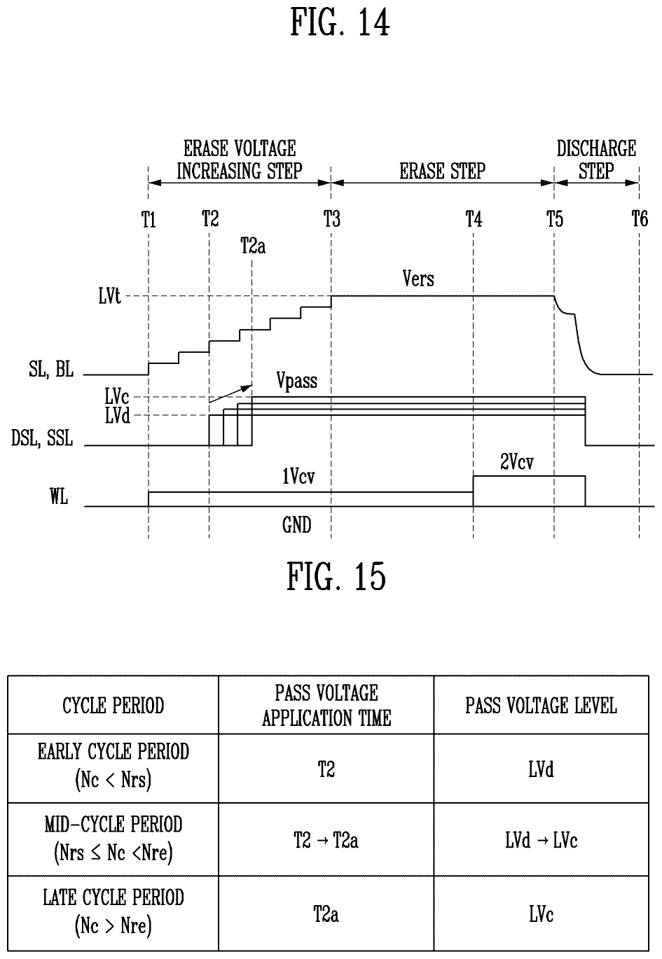

FIG. 14 is a timing diagram illustrating the erase operation according to the third embodiment of the present disclosure.

Referring to FIG. 14, the erase operation may include an erase voltage increasing step, an erase step, and a discharge step and may be performed during a period from time T1 to time T6. The erase voltage increasing step may be performed during a period from time T1 to time T3, the erase step may be performed during a period from time T3 to time T5, and the discharge step may be performed during a period from time T5 to time T6.

At time T1 at which the erase voltage increasing step starts, an erase voltage Vers may be applied to the source line SL and the bit lines BL, and a ground voltage GND and a first compensation voltage 1Vcv that is higher than the ground voltage GND may be applied to word lines WL. The erase voltage Vers may be set to a positive voltage that is higher than the ground voltage GND and may increase in a stepwise or continuous manner to a target level LVt. The first compensation voltage 1Vcv may be set to a positive voltage that is higher than the ground voltage GND and lower than the target level LVt of the erase voltage Vers. The first compensation voltage 1Vcv may be applied to the word lines WL to stably perform the erase operation at the erase step. Although, in the drawing, the first compensation voltage 1Vcv is illustrated as being applied to the word lines WL at time T1, it may be applied to the word lines WL within a period from time T1 to time T2.

During a period from time T1 to time T3 in which the erase voltage increasing step is performed, the pass voltage Vpass may be applied to the drain select line DSL and the source select line SSL. The pass voltage Vpass may be used to generate gate induced drain leakage (GIDL) during the erase operation and may be used to prevent the threshold voltages of the drain select transistor and the source select transistor from decreasing at the erase step. Therefore, the pass voltage Vpass may be set to a positive voltage that is higher than the ground voltage GND. For example, the pass voltage Vpass may have a default level LVd that is higher than the first compensation voltage 1Vcv and lower than the target level LVt of the erase voltage Vers.

The default level LVd of the pass voltage may be stored in advance in the memory device. Since time T2 at which the pass voltage Vpass is applied to the drain select line DSL and the source select line SSL is also the first default time, time T2 may be stored in advance in the memory device. When the cycle count of the memory block is less than the initial reference count, the pass voltage Vpass may be set to a default level LVd, and a time at which the pass voltage Vpass is applied may be set to time T2, which is the first default time. When the cycle count of the memory block is equal to or greater than the initial reference count, the pass voltage Vpass may be set to a level that is higher than the default level LVd, and the time at which the pass voltage Vpass is applied may be set to a time that is after time T2. When the cycle count of the memory block is equal to or greater than the initial reference count, the level of the pass voltage Vpass may be set to incrementally increase and the time at which the pass voltage Vpass is applied may be delayed incrementally more, as the cycle count increases. For example, as the cycle count increases, the pass voltage Vpass may incrementally increase from the default level LVd to the compensation level LVc, and the time at which the pass voltage Vpass is applied may be delayed incrementally more from time T2 to time T2a. The compensation level LVc may be set between the default level LVd and a level twice the default level LVd. Time T2a may be set between time T2 and time T3.

When time T3 at which the erase voltage Vers applied to the source line SL and the bit line BL reaches the target level LVt is reached, GIDL may be generated on the channel layer, and then the erase operation may be performed.

The erase step may be performed during a period from time T3 to time T5. While the erase step is being performed, a second compensation voltage 2Vcv may be applied to the word lines WL. For example, during a period from time T1 to time T4, the ground voltage GND or the first compensation voltage 1Vcv may be applied to the word lines WL, and from time T4, the second compensation voltage 2Vcv, which is greater than the first compensation voltage 1Vcv, may be applied to the word lines WL. The second compensation voltage 2Vcv may be used to prevent the potential of the channel layer from excessively decreasing at the discharge step. Therefore, the second compensation voltage 2Vcv may be set to be a voltage that is higher than the first compensation voltage 1Vcv or lower than the target level LVt of the erase voltage Vers.

During a period from time T5 to time T6, the source line SL and the bit line BL may be discharged stepwise, and the drain select line DSL, the source select line SSL, and the word lines WL may be simultaneously discharged.

FIG. 15 is a diagram illustrating a pass voltage application time and a pass voltage depending on a cycle period according to the third embodiment of the present disclosure.

Referring to FIGS. 14 and 15, the level of the pass voltage Vpass applied to the drain select line DSL and the source select line SSL during an erase operation and the time at which the pass voltage Vpass is applied may be changed depending on the cycle period of a memory block. The cycle period may be divided according to the cycle count Nc of the memory block. For example, a period in which the cycle count Nc is less than the initial reference count Nrs may be set as an early cycle period, a period in which the cycle count Nc is equal to or greater than the initial reference count Nrs and less than an end reference count Nre may be set as a mid-cycle period, and a period in which the cycle count Nc is greater than the end reference count Nre may be set as a late cycle period.

The early cycle period may be the period in which the cycle count Nc of the memory block is low, and in which degradation of the memory block does not occur even if the cycle count Nc increases. Therefore, during the early cycle period, the pass voltage having a constant default level LVd may be applied to the drain select line DSL and the source select line SSL at the second time T2, which is the first default time, regardless of the cycle count Nc.

The mid-cycle period may be a period in which the electrical characteristics of the memory block can be degraded as the cycle count Nc of the memory block increases. Therefore, during a mid-cycle period, the pass voltage may be changed incrementally from the default level LVd to the compensation level LVc depending on the cycle count Nc, and the time at which the pass voltage is applied to the drain select line DSL and the source select line SSL may also incrementally increase from time T2 to time T2a.

The late cycle period may be a period in which the cycle count Nc of the memory block is high and may be a period in which significant degradation of the memory block occurs. During the late cycle period, it is difficult to greatly improve the electrical characteristics even if the pass voltage application time is adjusted. The pass voltage having a constant compensation level LVc may be applied to the drain select line DSL and the source select line SSL at time T2a, regardless of the cycle count Nc.

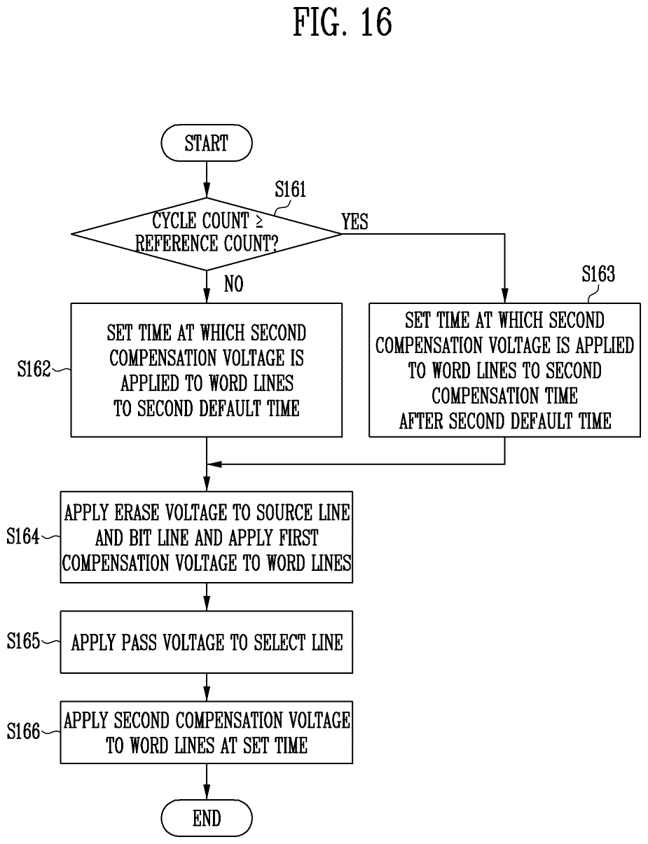

FIG. 16 is a flowchart illustrating an erase operation according to a fourth embodiment of the present disclosure.

Referring to FIG. 16, when an erase command and an address are input to the memory device, the memory device may compare the number of cycles (cycle count) Nc of a selected memory block with an initial reference count Nrs at step S161. The initial reference count Nrs may be set to the number of times corresponding to an early cycle period of the entire life cycle during which the memory device can be operated. The early cycle period may refer to a period during which the degree of degradation of the memory device is low and within a normal range even if the cycle count Nc increases. That is, a period during which, even when the program and erase operations are performed, the reliability of the memory device does not deteriorate or deteriorates only slightly may be defined as the early cycle period. The initial reference count Nrs may be stored in the control circuit (e.g., 170 of FIG. 1) of the memory device.

The control circuit (e.g., 170 of FIG. 1) of the memory device may determine whether the cycle count Nc of the selected memory block is equal to or greater than the initial reference count Nrs. When the cycle count Nc is less than the initial reference count Nrs (in the case of “No”), the control circuit (e.g., 170 of FIG. 1) may set a time at which a second compensation voltage 2Vcv is applied to word lines to be a second default time at step S162. Here, the second default time refers to a time basically set in the memory device.

When the cycle count Nc is equal to or greater than the initial reference count Nrs (in the case of “Yes”) at step S161, the control circuit (e.g., 170 of FIG. 1) may set the time at which the second compensation voltage is applied to the word lines to be a second compensation time that is after the second default time at step S163. For example, the second compensation time may be a time that is later than the second default time.

When the time at which the second compensation voltage is applied is set at step S162 or S163, an erase voltage may be applied to a source line and a bit line connected to the selected memory block, and the first compensation voltage may be applied to the word lines at step S164. The erase voltage may be a voltage for erasing the memory cells included in the selected memory block and may be set to a positive voltage higher than 0 V. The first compensation voltage may be applied to the word lines so as to stably perform an erase operation at the erase step. The erase voltage may be applied only to the source line or to the bit line, but, in the present embodiment, the case in which the erase voltage is applied to the source line and the bit line is described by way of example. Even if the erase voltage is applied to the source line and the bit line, it may take a certain time for the potentials of the source line and the bit line to reach the target level of the erase voltage.

During a period in which the erase voltage is applied to the source line and the bit line and the erase voltage is increasing to the target level, the pass voltage may be applied to the select line at step S165. The pass voltage may refer to a voltage at which a drain select transistor and a source select transistor can be turned on.

While the erase operation is being performed, a second compensation voltage, higher than the first compensation voltage, may be applied at the set time to the word lines to which the first compensation voltage is applied at step S166. The set time used at step S166 may refer to the time set at step S162 or S163. Therefore, when the time at which the second compensation voltage is applied is set at step S162, the second compensation voltage may be applied to the word lines at the second default time at step S166. When the time at which the second compensation voltage is applied is set at step S163, the second compensation voltage may be applied to the word lines at the second compensation time at step S166.

That is, when the cycle count of the selected memory block is less than the initial reference count, the second compensation voltage may be applied to the word lines at the second default time during the erase operation, whereas when the cycle count of the selected memory block is equal to or greater than the initial reference count, the second compensation voltage may be applied to the word lines at the second compensation time that is later than the second default time during the erase operation.

During the erase operation according to the fourth embodiment, a method of applying voltages to lines connected to the selected memory block will be described in detail below.

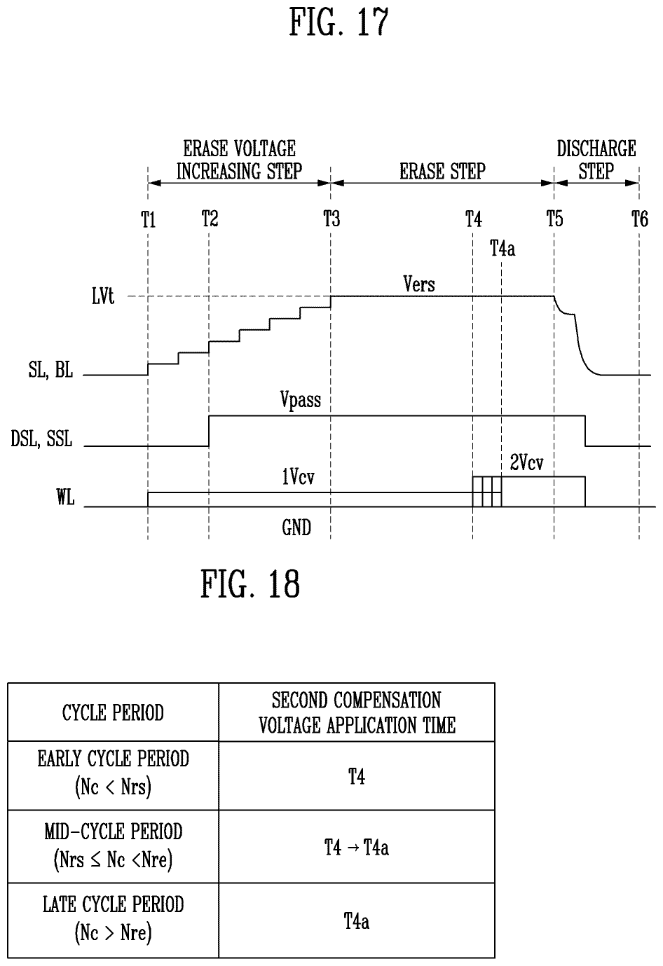

FIG. 17 is a timing diagram illustrating the erase operation according to the fourth embodiment of the present disclosure.

Referring to FIG. 17, the erase operation may include an erase voltage increasing step, an erase step, and a discharge step and may be performed during a period from time T1 to time T6. The erase voltage increasing step may be performed during a period from time T1 to time T3, the erase step may be performed during a period from time T3 to time T5, and the discharge step may be performed during a period from time T5 to time T6.

At time T1 at which the erase voltage increasing step starts, an erase voltage Vers may be applied to the source line SL and the bit lines BL, and a ground voltage GND and a first compensation voltage 1Vcv that is higher than the ground voltage GND may be applied to word lines WL. The erase voltage Vers may be set to a positive voltage that is higher than the ground voltage GND and may increase in a stepwise or continuous manner to a target level LVt. The first compensation voltage 1Vcv may be set to a positive voltage that is higher than the ground voltage GND and lower than the target level LVt of the erase voltage Vers. The first compensation voltage 1Vcv may be applied to the word lines WL to stably perform the erase operation at the erase step. Although, in the drawing, the first compensation voltage 1Vcv is illustrated as being applied to the word lines WL at time T1, it may be applied to the word lines WL within a period from time T1 to time T2.

During a period from time T1 to time T3 in which the erase voltage increasing step is performed, the pass voltage Vpass may be applied to the drain select line DSL and the source select line SSL. The pass voltage Vpass may be used to generate gate induced drain leakage (GIDL) during the erase operation and may be used to prevent the threshold voltages of the drain select transistor and the source select transistor from decreasing at the erase step. Therefore, the pass voltage Vpass may be set to a positive voltage that is higher than the ground voltage GND. For example, the pass voltage Vpass may be set to a voltage that is higher than the first compensation voltage 1Vcv or lower than the target level LVt of the erase voltage Vers.

Time T2 at which the pass voltage Vpass is applied to the drain select line DSL and the source select line SSL may be a first default time stored in advance in the memory device.

When time T3 at which the erase voltage Vers applied to the source line SL and the bit line BL reaches the target level LVt is reached, GIDL may be generated on the channel layer, and then the erase operation may be performed.

The erase step may be performed during a period from time T3 to time T5. While the erase step is being performed, a second compensation voltage 2Vcv may be applied to the word lines WL. For example, during a period from time T1 to time T4, the ground voltage GND or the first compensation voltage 1Vcv may be applied to the word lines WL, and from time T4, the second compensation voltage 2Vcv, which is greater than the first compensation voltage 1Vcv, may be applied to the word lines WL. The second compensation voltage 2Vcv may be used to prevent the potential of the channel layer from excessively decreasing at the discharge step. Therefore, the second compensation voltage 2Vcv may be set to be a voltage that is higher than the first compensation voltage 1Vcv or lower than the target level LVt of the erase voltage Vers.

When the cycle count of the memory block is less than the initial reference count, the time at which the second compensation voltage 2Vcv is applied may be set to time T4, which is the second default time. When the cycle count of the memory block is equal to or greater than the initial reference count, the time at which the second compensation voltage 2Vcv is applied may be set to a time that is after time T4. When the cycle count of the memory block is equal to or greater than the initial reference count, the time at which the second compensation voltage 2Vcv is applied may be delayed incrementally more as the cycle count increases. For example, as the cycle count increases, the time at which the second compensation voltage 2Vcv is applied may be delayed stepwise from time T4 to time T4a. Time T4a may be a second compensation time that is set between time T4 and time T5.

During a period from time T5 to time T6, the source line SL and the bit line BL may be discharged stepwise, and the drain select line DSL, the source select line SSL, and the word lines WL may be simultaneously discharged.

FIG. 18 is a diagram illustrating a second compensation voltage application time depending on a cycle period according to the fourth embodiment of the present disclosure.

Referring to FIGS. 17 and 18, the time at which the second compensation voltage 2Vcv is applied to word lines WL during an erase operation may be changed depending on the cycle period of the memory block. The cycle period may be divided according to the cycle count Nc of the memory block. For example, a period in which the cycle count Nc is less than the initial reference count Nrs may be set as an early cycle period, a period in which the cycle count Nc is equal to or greater than the initial reference count Nrs and less than an end reference count Nre may be set as a mid-cycle period, and a period in which the cycle count Nc is greater than the end reference count Nre may be set as a late cycle period.

The early cycle period may be the period in which the cycle count Nc of the memory block is low, and in which degradation of the memory block does not occur even if the cycle count Nc increases. Therefore, during the early cycle period, the second compensation voltage 2Vcv may be applied to the word lines WL at the fourth time T4, which is the second default time, regardless of the cycle count Nc.

The mid-cycle period may be a period in which the electrical characteristics of the memory block can be degraded as the cycle count Nc of the memory block increases. Therefore, during the mid-cycle period, the time at which the second compensation voltage 2Vcv is applied may be changed incrementally from time T4 to time T4a depending on the cycle count Nc.

The late cycle period may be a period in which the cycle count Nc of the memory block is high and may be a period in which significant degradation of the memory block occurs. During the late cycle period, it is difficult to greatly improve electrical characteristics even if the time at which the second compensation voltage 2Vcv is applied is adjusted. The second compensation voltage 2Vcv may be applied to the word lines WL at time T4a, regardless of the cycle count Nc.

The above-described first to fourth embodiments may be combined with each other.

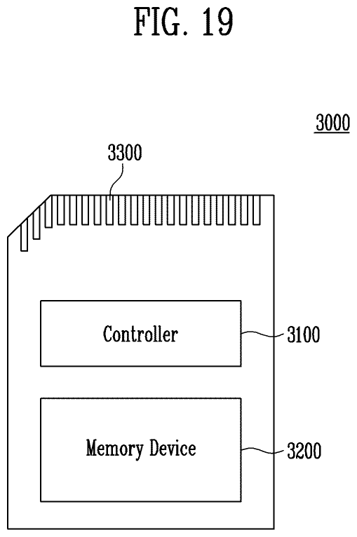

FIG. 19 is a diagram illustrating a memory card system to which a memory system according to an embodiment of the present disclosure is applied.

Referring to FIG. 19, a memory card system 3000 may include a controller 3100, a memory device 3200, and a connector 3300.

The controller 3100 may be connected to the memory device 3200. The controller 3100 may access the memory device 3200. For example, the controller 3100 may control a program operation, a read operation, or an erase operation of the memory device 3200 or may control background operations of the memory device 3200. The controller 3100 may provide an interface between the memory device 3200 and a host. The controller 3100 may run firmware that controls the memory device 3200. For example, the controller 3100 may include components, such as a random access memory (RAM), a processor, a host interface, a memory interface, and an error correction circuit.

The controller 3100 may communicate with an external device through the connector 3300. The controller 3100 may communicate with an external device (e.g., a host) based on a specific communication standard. In an embodiment, the controller 3100 may communicate with the external device through at least one of the following various communication standards: universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe), etc. In an embodiment, the connector 3300 may be defined by at least one of the above-described various communication standards.

The memory device 3200 may include memory cells and may be configured in the same manner as the memory device 100 illustrated in FIG. 1.

The controller 3100 and the memory device 3200 may be integrated into a single semiconductor device to form a memory card. For example, the controller 3100 and the memory device 3200 may be integrated into a single semiconductor device and may then form a memory card, such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), universal flash storage (UFS), or the like.

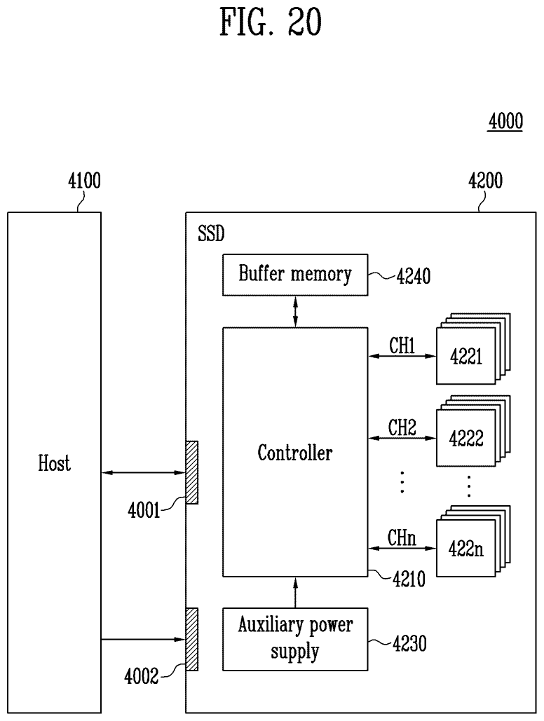

FIG. 20 is a diagram illustrating a solid state drive (SSD) system to which a memory device according to an embodiment of the present disclosure is applied.

Referring to FIG. 20, an SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. In an embodiment, the signals may be signals based on the interfaces of the host 4100 and the SSD 4200. For example, the signals may be signals defined by at least one of the following interfaces: universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, nonvolatile memory express (NVMe), etc.

Each of the plurality of memory devices 4221 to 422n may include cells in which data can be stored. Each of the plurality of memory devices 4221 to 422n may be configured in the same manner as the memory device 100 illustrated in FIG. 1.

The auxiliary power supply 4230 may be connected to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located on a main board and may also provide auxiliary power to the SSD 4200.

The buffer memory 4240 may function as a buffer memory of the SSD 4200. For example, the buffer memory 4240 may temporarily store data received from the host 4100 or data received from the plurality of memory devices 4221 to 422n or may temporarily store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

According to the present disclosure, even if the cycle count of a memory device increases, the reliability of the memory device may be prevented from deteriorating.

What is claimed is:

1. A memory device, comprising:
a memory block including first and second select transistors connected between a source line and a bit line, and memory cells connected between the first and second select transistors;
a peripheral circuit configured to adjust threshold voltages of the first and second select transistors and the memory cells; and
a control circuit configured to, depending on a cycle count of the memory block during an erase operation on the memory block, control the peripheral circuit to adjust a pass voltage that is applied to a first select line connected to a gate of the first select transistor and to a second select line connected to a gate of the second select transistor.

2. The memory device according to claim 1, wherein the control circuit is configured to control the peripheral circuit to apply the pass voltage to the first and second select lines while an erase voltage applied to at least one of the source line and the bit line is increasing up to a target level.

3. The memory device according to claim 1, wherein the control circuit is configured to:
store an initial reference count of the memory block,
compare the cycle count of the memory block with the initial reference count, and
adjust the pass voltage that is applied to the first and second select lines.

4. The memory device according to claim 3, wherein the control circuit is configured to adjust a time at which the pass voltage is applied to the first and second select lines based on a result of the comparison between the cycle count and the initial reference count.

5. The memory device according to claim 4, wherein the control circuit is configured to, when the cycle count is less than the initial reference count, maintain the time at which the pass voltage is applied to the first and second select lines at a first default time.

6. The memory device according to claim 5, wherein the control circuit is configured to, when the cycle count is equal to or greater than the initial reference count, delay the time at which the pass voltage is applied to the first and second select lines from the first default time.

7. The memory device according to claim 5, wherein the control circuit is configured to, when the cycle count is equal to or greater than the initial reference count and is less than an end reference count that is greater than the initial reference count, incrementally delay the time at which the pass voltage is applied to the first and second select lines from the first default time to a first compensation time depending on the cycle count.

8. The memory device according to claim 7, wherein the control circuit is configured to, when the cycle count is equal to or greater than the end reference count, maintain the time at which the pass voltage is applied to the first and second select lines at the first compensation time.

9. The memory device according to claim 3, wherein the control circuit is configured to adjust a level of the pass voltage based on a result of the comparison between the cycle count and the initial reference count.

10. The memory device according to claim 9, wherein the control circuit is configured to, when the cycle count is less than the initial reference count, maintain the level of the pass voltage at a default level.

11. The memory device according to claim 10, wherein the control circuit is configured to, when the cycle count is equal to or greater than the initial reference count, increase the level of the pass voltage above the default level.

12. The memory device according to claim 10, wherein the control circuit is configured to, when the cycle count is equal to or greater than the initial reference count and less than an end reference count that is greater than the initial reference count, incrementally increase the level of the pass voltage from the default level to a compensation level depending on the cycle count.

13. The memory device according to claim 12, wherein the control circuit is configured to, when the cycle count is equal to or greater than the end reference count, maintain the level of the pass voltage at the compensation level.

14. The memory device according to claim 1, wherein the control circuit is configured to, while an erase voltage applied to at least one of the source line and the bit line is maintained at a target level, control the peripheral circuit to adjust a compensation voltage that is applied to word lines connected to gates of the memory cells.

15. The memory device according to claim 14, wherein the control circuit is configured to:
store an initial reference count of the memory block,
compare the cycle count of the memory block with the initial reference count, and
adjust a time at which the compensation voltage is applied to the word lines.

16. The memory device according to claim 15, wherein the control circuit is configured to, when the cycle count is less than the initial reference count, maintain the time at which the compensation voltage is applied to the word lines at a second default time.

17. The memory device according to claim 16, wherein the control circuit is configured to, when the cycle count is equal to or greater than the initial reference count, delay the time at which the compensation voltage is applied to the word lines from the second default time.

18. The memory device according to claim 16, wherein the control circuit is configured to, when the cycle count is equal to or greater than the initial reference count and less than an end reference count that is greater than the initial reference count, incrementally delay the time at which the compensation voltage is applied to the word lines from the second default time to a second compensation time depending on the cycle count.

19. The memory device according to claim 16, wherein the control circuit is configured to, when the cycle count is equal to or greater than the end reference count, maintain the time at which the compensation voltage is applied to the word lines at the second compensation time.
